(19) United States
(12) Patent Application Publication
(10) Pub. No.: US 2024/0188333 A1
(43) Pub. Date: Jun. 6, 2024

(54) DISPLAY DEVICE

(71) Applicant: Samsung Display Co., LTD., Yongin-si (KR)

(72) Inventor: Yoshiaki SAKAMOTO, Yongin-si (KR)

(21) Appl. No.: 18/219,851

(22) Filed: Jul. 10, 2023

(30) Foreign Application Priority Data
Dec. 5, 2022 (KR) 10-2022-0167532

(51) Int. Cl. H10K 59/122; H10K 59/121; H10K 59/131; H10K 59/80

(52) U.S. Cl. CPC H10K 59/122; H10K 59/1213; H10K 59/1315; H10K 59/80515

(57) ABSTRACT

A display device includes a substrate, a first electrode disposed on the substrate, a pixel-defining film including a plurality of open portions exposing the first electrode, a plurality of emissive layers overlapping with a monolithic surface of the first electrode in a plan view and disposed in the plurality of open portions, respectively, and a second electrode disposed on the plurality of emissive layers.

This application claims priority to Korean Patent Application No. 10-2022-0167532, filed on Dec. 5, 2022, and all the benefits accruing therefrom under 35 U.S.C. § 119, the content of which in its entirety is herein incorporated by reference.

### BACKGROUND

### 1. Field of the Disclosure

The present disclosure relates to a display device.

### 2. Description of the Related Art

A display device becomes more and more important as multimedia technology evolves. Such a display device may be sorted into a non-emissive display device such as a liquid crystal display (“LCD”), and an emissive display device such as organic light-emitting display (“OLED”).

In order to form an emissive layer of an emissive display device, research is ongoing on the technique that forms an emissive layer by spraying an organic or inorganic ink containing a self-luminous material by solution-coating such as inkjet printing and then drying it.

When the display device is fabricated by using such an inkjet printing technique, the edge becomes thicker than the central portion due to the coffee-ring effect during the process of drying the ink.

### SUMMARY

Aspects of the present disclosure provide a display device with improved uniformity of the film thickness and luminance by suppressing the coffee ring effect.

Aspects of the present disclosure also provide a display device with improved uniformity of the film thickness and luminance by reducing level differences under the emissive layer.

It should be noted that aspects of the present disclosure are not limited to the above-mentioned aspects: and other aspects of the present disclosure will be apparent to those skilled in the art from the following descriptions.

According to an aspect of the present disclosure, a display device includes a substrate, a first electrode disposed on the substrate, a pixel-defining film including a plurality of open portions exposing the first electrode, a plurality of emissive layers overlapping with a monolithic surface of the first electrode in a plan view and disposed in the plurality of open portions, respectively, and a second electrode disposed on the plurality of emissive layers.

In an embodiment, at least a portion of an upper surface of the first electrode overlapping with the open portions may be flat.

In an embodiment, the first electrode may include a reference surface located on the upper surface of the first electrode and protruding portions that are higher than the reference surface, and outermost boundaries of the protruding portions may not overlap with the exposed portion of the first electrode in the plan view.

In an embodiment, the protruding portion may not overlap with the exposed portion of the first electrode in the plan view.

In an embodiment, the protruding portions may overlap with the exposed portion of the first electrode as well as other portions of the first electrode except for the exposed portion in the plan view.

In an embodiment, the display device may further include a circuit layer disposed between the substrate and the first electrode, and the circuit layer may include signal lines and thin-film transistors, and the signal lines and the thin-film transistors may not overlap with the open portions in the plan view.

In an embodiment, the signal lines may include at least one of a data line, a sensing signal line, a scan line, a reference voltage line, and a first supply voltage line.

In an embodiment, the signal lines may be arranged to be spaced apart from the open portions when viewed from top, and where the signal lines may overlap with at least one of the plurality of open portions in a cross-sectional view, and surround at least a part of the at least one open portion in the plan view.

In an embodiment, the signal lines may surround an entirety of the at least one open portion in the plan view.

In an embodiment, the display device may be further include a circuit layer disposed between the substrate and the first electrode, and the circuit layer may include signal lines and thin-film transistors, and an entirety of at least one of the open portions may overlap with the signal lines in the plan view.

In an embodiment, a width of the signal lines may be greater than or equal to a width of the at least one open portion in an area where the signal line overlaps with the at least one open portion.

In an embodiment, the first electrode may be a single surface electrode.

In an embodiment, the first electrode may include a plurality of patterned sub-electrodes, the sub-electrodes may be electrically connected with one another, and each of the sub-electrodes may be overlap with at least one of the plurality of emissive layers in the plan view.

In an embodiment, the second electrode may be in direct contact with the pixel-defining film at side surfaces of the open portions.

In an embodiment, the second electrode may be in direct contact with an upper surface of the pixel-defining film disposed on an area other than the open portions.

In an embodiment, a shape of each of the open portions may have a point symmetry with respect to its center when viewed from top.

In an embodiment, in an emissive layer of the plurality of emissive layers, a height of an upper surface of the emissive layer may increase from a center to an edge of the emissive layer, and the upper surface of the emissive layer may have a shape concave toward the substrate.

In an embodiment, the emissive layer may include a light-emitting portion and a non-light-emitting portion surrounding the light-emitting portion, and deviation between a minimum height and a maximum height of the emissive layer in the light-emitting portion may be equal to or less than 100 angstroms (Å).

According to an aspect of the present disclosure, a display device includes: a substrate, a first electrode disposed on the substrate, a plurality of emissive layers spaced apart from one another on a monolithic surface of the first electrode and including an organic material, and a second electrode disposed on the plurality of emissive layers, where each of the plurality of emission layers overlaps with the first electrode and the second electrode.

In an embodiment, the plurality of emissive layers may be configured to diode-connect the first electrode with the second electrode.

According to an embodiment of the present disclosure, the uniformity of the film thickness and the luminance of a display device can be effectively improved by suppressing the coffee ring effect.

According to an embodiment of the present disclosure, the uniformity of the film thickness and the luminance of a display device can be improved by reducing level differences under the emissive layer.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to an embodiment of the present disclosure.

FIG. 2 is a view showing a layout of a circuitry of a display device according to an embodiment.

FIG. 3 is an equivalent circuit diagram of a sub-pixel of a display device according to an embodiment of the present disclosure.

FIG. 4 is a plan view showing pixels of a display device according to an embodiment of the present disclosure.

FIG. 5 is a plan view showing a positional relationship between open portions of a pixel-defining film and other elements.

FIG. 6 is a cross-sectional view taken along line I-I′ of FIG. 5.

FIG. 7 is an enlarged view of part A of FIG. 6.

FIG. 8 is an enlarged view of part B of FIG. 6.

FIGS. 9A and 9B are plan views for comparing light-emitting portions of a sub-pixel according to the embodiment with a light-emitting portion of an existing sub-pixel.

FIGS. 10A and 10B are graphs showing variations in the thickness of the emissive layer depending on the amount of an ink ejected into an open portion.

FIG. 11 is a graph showing the width of a coffee ring versus the drop volume of an ink ejected onto an open portion.

FIG. 12 is a plan view showing a pixel of a display device according to another embodiment of the present disclosure.

FIG. 13 is a plan view showing a sub-pixel of a display device according to yet another embodiment of the present disclosure.

FIG. 14 is a cross-sectional view taken along line II-II′ in FIG. 13.

FIG. 15 is a plan view showing a pixel of a display device according to the embodiment of the present disclosure.

FIG. 16 is a plan view showing a sub-pixel of a display device according to yet another embodiment of the present disclosure.

FIG. 17 is a cross-sectional view taken along line III-III′ of FIG. 16.

FIG. 18 is an enlarged view of part D of FIG. 17.

FIG. 19 is a plan view showing a sub-pixel of a display device according to yet another embodiment of the present disclosure.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, detailed embodiments will be described with reference to the accompanying drawings.

Hereinafter, embodiments of the present disclosure will be described with reference to the accompanying drawings.

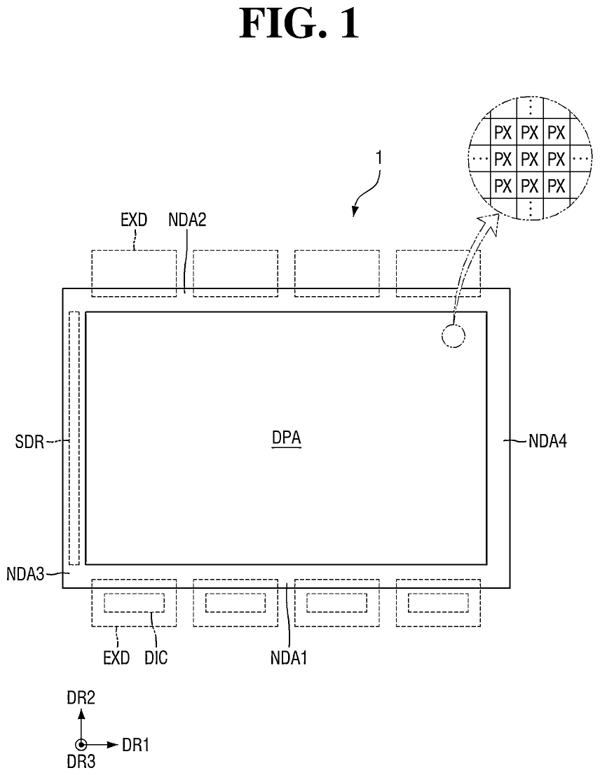

FIG. 1 is a plan view of a display device according to an embodiment of the present disclosure.

Referring to FIG. 1, a display device 1 according to an embodiment of the present disclosure may be applied to, a smart phone, a mobile phone, a tablet PC, a personal digital assistant (“PDA”), a portable multimedia player (“PMP”), a television set, a game machine, a wristwatch-type electronic device, a head-mounted display, a personal computer monitor, a laptop computer, a car navigation system, a car instrument cluster, a digital camera, a camcorder, an outdoor billboard, an electronic billboard, various medical apparatuses, various home appliances such as a refrigerator and a laundry machine, Internet of things (“IoT”) devices, etc. In the following description, a television is described as an example of the display device. TV may have a high resolution or ultra high resolution such as HD, UHD, 4K and 8K.

In addition, the display device 1 according to the embodiment may be variously classified by the way in which images are displayed. Examples of the classification of display devices may include an organic light-emitting display device (OLED), an inorganic light-emitting display device (inorganic EL), a quantum-dot light-emitting display device (“QED”), a micro LED display device (micro-LED), a nano LED display device (nano-LED), a plasma display device (“PDP”), a field emission display device (“FED”) and a cathode ray display device (“CRT”), a liquid-crystal display device (LCD), an electrophoretic display device (“EPD”), etc. Any other display device listed above or well known in the art may be employed as the display device 1 according to the embodiment without departing from the scope of the present disclosure.

According to the embodiment, the display device 1 may have a square shape, e.g., a rectangular shape when viewed from the top (i.e., in a plan view).

The display device 1 may include a display area DPA and a non-display area NDA. The display area DPA may be an active area where images are displayed. The display area DPA may have, but is not limited to, a rectangular shape similar to the general shape of the display device 1 when viewed from the top.

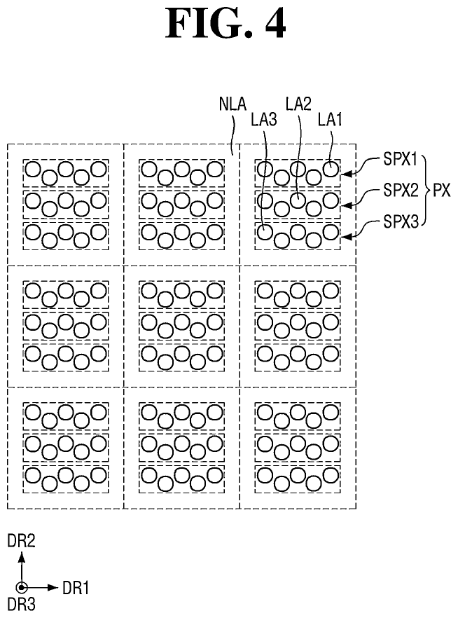

The display area DPA may include a plurality of pixels PX. The plurality of pixels PX may be arranged in a matrix. The shape of each of the pixels PX may be, but is not limited to, a rectangle or a square when viewed from the top. Each of the pixels PX may have a diamond shape having sides inclined with respect to a side of the display device 1. The plurality of pixels PX may include sub-pixels SPX (see FIG. 4) configured to represent a variety of colors. The pixels PX and the sub-pixels SPX will be described in detail later with reference to FIG. 4.

The non-display area NDA may be disposed around the display area DPA. The non-display area NDA may surround the display area DPA entirely or partially. The display area DPA may have a rectangular shape, and the non-display area NDA may be disposed to be adjacent to the four sides of the display area DPA. The non-display area NDA may form the bezel of the display device 1.

In the non-display areas NDA, a driving circuit or a driving element for driving the display area DPA may be disposed. According to an embodiment of the present disclosure, a pad area is disposed on the display substrate of the display device 1 in a first non-display area NDA1 disposed adjacent to a first longer side (the lower side in FIG. 1) of the display device 1 and a second non-display area NDA2 adjacent to a second longer side (the upper side in FIG. 1) of the display device 1. An external device EXD may be mounted on a pad electrode of the pad area. Examples of the external devices EXD may include a connection film, a printed circuit board, a driver chip DIC, a connector, a line connection film, etc. A scan driver SDR formed directly on the display substrate of the display device 1 may be disposed in the third non-display area NDA3 disposed adjacent to a first shorter side of the display device 1 (the left side in FIG. 1).

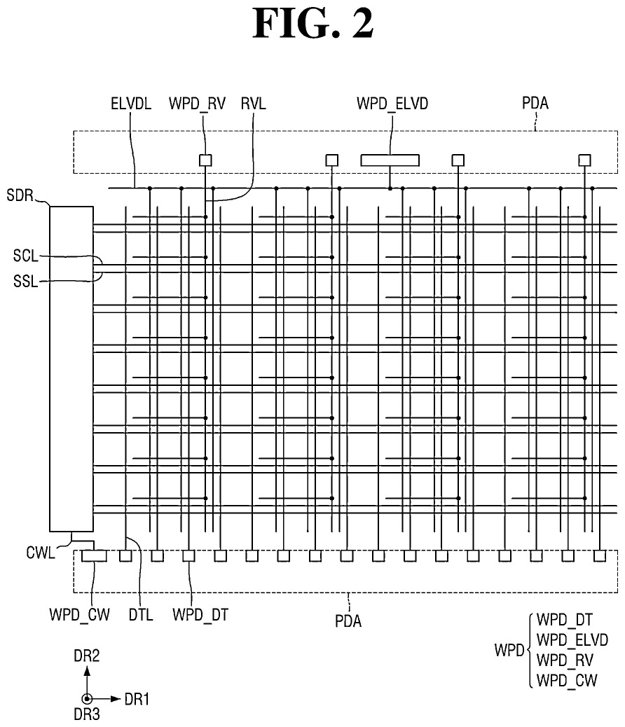

FIG. 2 is a view showing a layout of a circuitry of a display device according to an embodiment.

Referring to FIG. 2, a plurality of signal lines is disposed on the substrate. The plurality of signal lines may include a scan line SCL, a sensing signal line SSL, a data line DTL, a reference voltage line RVL, a first supply voltage line ELVDL, etc.

The scan line SCL and the sensing signal line SSL may be extended in the first direction DR1. The scan line SCL and the sensing signal line SSL may be connected to the scan driver SDR. The scan driver SDR may include a driving circuit formed of a driving circuit layer CCL. The scan driver SDR may be disposed in the third non-display area NDA3 on the substrate, but the present disclosure is not limited thereto. The scan driver SDR may be disposed in a fourth non-display area NDA4 or both the third non-display area NDA3 and the fourth non-display area NDA4. The scan driver SDR may be connected to a signal connection line CWL. At least one end of the signal connection line CWL may form a pad WPD_CW on the first non-display area NDA1 and/or the second non-display area NDA2 and may be connected to an external device EXD (see FIG. 1).

In the drawings, the first direction DR1 and the second direction DR2 intersect each other as the horizontal directions. For example, the first direction D1 and the second direction D2 may be perpendicular to each other. In addition, a third direction DR3 may intersect the first direction DR1 and the second direction DR2, and may be a vertical direction, for example. Herein, the side indicated by the arrow of each of the first to third directions DR1, DR2 and DR3 may be referred to as a first side, while the opposite side may be referred to as a side opposite side.

The data line DTL and the reference voltage line RVL may be extended in the second direction DR2 crossing the first direction DR1. A first supply voltage line ELVDL may include a portion extending in the second direction DR2. The first supply voltage line ELVDL may further include a portion extending in the first direction DR1. The first supply voltage line ELVDL may have, but is not limited to, a mesh structure.

The wire pads WPD may be disposed at at least one end of the data line DTL, the reference voltage line RVL, and the first supply voltage line ELVDL. The wire pads WPD may be disposed in the pad area PDA of the non-display area NDA. According to an embodiment of the present disclosure, a wire pad WPD_DT of the data line DTL (hereinafter, referred to as a data pad) may be disposed in the pad area PDA of the first non-display area NDA1. A wire pad WPD_RV of the reference voltage line RVL (hereinafter referred to as a reference voltage pad) and a wire pad WPD_ELVD of the first supply voltage line ELVDL (hereinafter referred to as a first supply voltage pad) may be disposed in the pad area PDA of the second non-display area NDA2. As another example, the data pad WPD_DT, the reference voltage pad WPD_RV and the first supply voltage pad WPD_ELVD may all be disposed in the same area, e.g., the first non-display area NDA1. As described above, the external devices EXD (see FIG. 1) may be mounted on the wire pad WPD. The external devices EXD may be mounted on the wire pads WPD by an anisotropic conductive film, ultrasonic bonding, etc.

Each of the pixels PX or the sub-pixels SPX (see FIG. 4) on the substrate includes a pixel driving circuit. The above-described signal lines may pass through the pixels PX, the sub-pixels SPX or the periphery thereof to apply a driving signal to the pixel driving circuit. The pixel driving circuit may include transistors and a capacitor. The numbers of transistors and capacitors of each pixel driving circuit may be changed in a variety of ways. In the following description, the pixel driving circuit having a 3T1C structure including three transistors and one capacitor will be described as an example. It is, however, to be understood that the present disclosure is not limited thereto. A variety of modified pixel structure may be employed such as a 2T1C (two transistors and one capacitor) structure, a 7T1C (seven transistors and one capacitor) structure and a 6T1C (six transistors and one capacitor) structure.

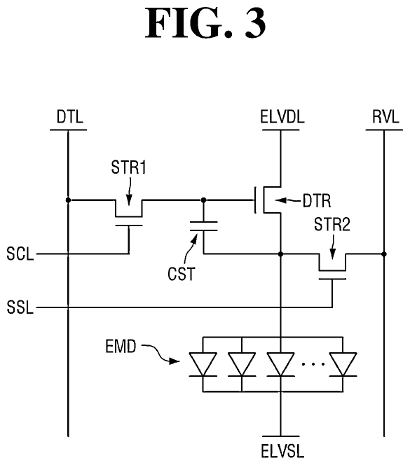

FIG. 3 is an equivalent circuit diagram of a sub-pixel of a display device according to an embodiment of the present disclosure.

Referring to FIG. 3, each of the sub-pixels SPX (see FIG. 4) of the display device according to the embodiment includes three transistors DTR, STR1 and STR2 and one storage capacitor CST in addition to a light-emitting element EMD.

The light-emitting element EMD emits light in proportional to the current supplied through the driving transistor DTR. The light-emitting element EMD may be implemented as an organic light-emitting element, a micro light-emitting element, a nano light-emitting element, etc.

The first electrode (i.e., the anode electrode) of the light-emitting element EMD may be connected to the source electrode of the driving transistor DTR, and the second electrode (i.e., the cathode electrode) thereof may be connected to a second supply voltage line ELVSL, from which a low-level voltage (second supply voltage) is applied, lower than a high-level voltage (first supply voltage) of a first supply voltage line ELVDL.

In the display device 1 according to the embodiment, a plurality of light-emitting elements EMD may be formed. The light-emitting elements EMD may be connected in parallel with one another.

The driving transistor DTR adjusts a current flowing from the first supply voltage line ELVDL from which the first supply voltage is applied to the light-emitting element EMD according to the voltage difference between the gate electrode and the source electrode. The gate electrode of the driving transistor DTR may be connected to a source/drain electrode of the first switching transistor STR1, the source electrode may be connected to a first electrode of the light-emitting element EMD, and the drain electrode may be connected to the first supply voltage line ELVDL from which the first supply voltage is applied.

The first switching transistor STR1 is turned on by a scan signal of a scan line SCL to connect a data line DTL with the gate electrode of the driving transistor DTR. A gate electrode of the first switching transistor STR1 may be connected to the scan line SCL, the first source/drain electrode may be connected to the gate electrode of the driving transistor DTR1, and a second source/drain electrode thereof may be connected to the data line DTL.

The second switching transistor STR2 may be turned on by a sensing signal of a sensing signal line SSL to connect a reference voltage line RVL to the source electrode of the driving transistor DTR. A gate electrode of the second switching transistor ST2 may be connected to the sensing signal line SSL, the first source/drain electrode thereof may be connected to the reference voltage line RVL, and the second source/drain electrode thereof may be connected to the source electrode of the driving transistor DTR.

According to an embodiment of the present disclosure, the first source/drain electrode of each of the first and second switching transistors STR1 and STR2 may be a source electrode while the second source/drain electrode thereof may be a drain electrode. It is, however, to be understood that the present disclosure is not limited thereto. The first source/drain electrode of each of the first and second switching transistors STR1 and STR2 may be a drain electrode while the second source/drain electrode thereof may be a source electrode.

The capacitor CST may be formed between the gate electrode and the source electrode of the driving transistor DTR. The capacitor CST stores the voltage equal to the difference between the gate voltage and the source voltage of the driving transistor DTR.

The driving transistor DTR and the first and second switching transistors STR1 and STR2 may be formed as thin-film transistors. In addition, although FIG. 3 shows that each of the driving transistor DTR and the first and second switching transistors STR1 and STR2 is implemented as an n-type metal oxide semiconductor field effect transistor (MOSFET), it is to be noted that the present disclosure is not limited thereto. That is to say, the driving transistor DTR and the first and second switching transistors STR1 and STR2 may be implemented as p-type MOSFETs, or some of them may be implemented as n-type MOSFETs while the others may be implemented as p-type MOSFETs.

FIG. 4 is a plan view showing pixels of a display device according to an embodiment of the present disclosure. As used herein, the “plan view: is a view in a thickness direction (i.e., third direction DR3) of the substrate 110.

The pixels PX may include sub-pixels SPX (see FIG. 4) configured to represent a variety of colors. For example, the pixels PX may include, but are not limited to, first sub-pixels SPX1 representing a first color, second sub-pixels SPX2 representing a second color, and third sub-pixels SPX3 representing a third color. The sub-pixels SPX may be arranged alternately in RGB stripes or a PenTile matrix.

A plurality of emission areas LA1, LA2 and LA3 and a non-emission area NLA may be defined on the substrate in the display area DPA. In some embodiments, a plurality of emission areas LA1, LA2 and LA3 in the display area DPA may include a first emission area LA1, a second emission area LA2 and a third emission area LA3. In the first, second and third emission areas LA1, LA2 and LA3, lights generated in the light-emitting elements of the substrate may exit to the outside. In the non-emission area NLA, no lights exit to the outside.

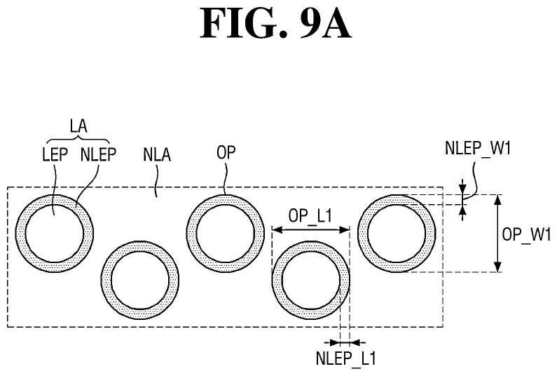

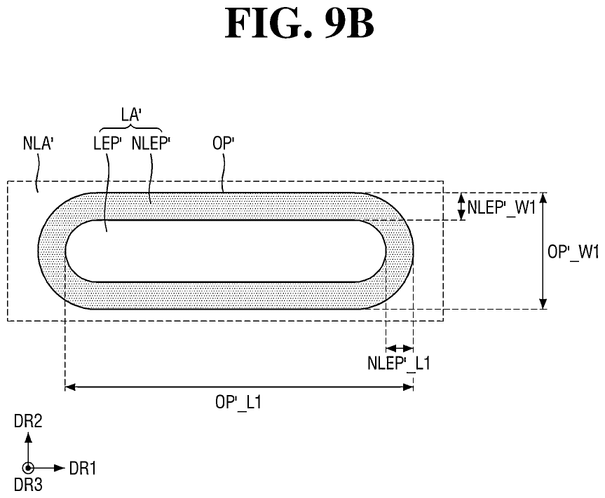

As will be described later with reference to FIG. 9A and the like, in some embodiments, each of the emission areas LA1, LA2 and LA3 may include a light-emitting portion LEP (see FIG. 9A) and a non-light-emitting portion NLEP (see FIG. 9A). The non-light-emitting portion NLEP refers to a region that does not emit light due to a coffee ring effect. The light-emitting portion LEP and the non-light-emitting portion NLEP will be described in detail later with reference to FIG. 9A and the like.

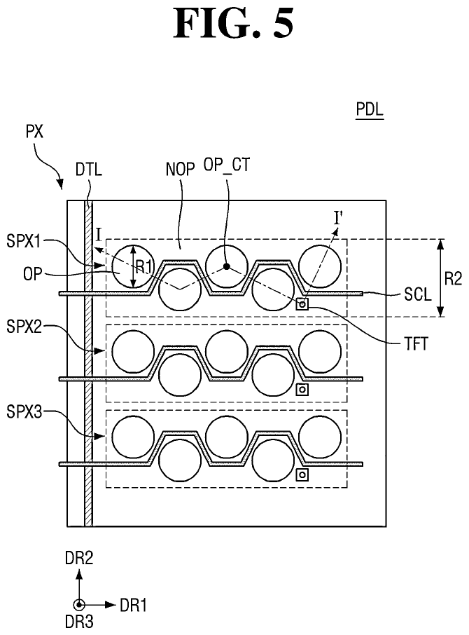

The plurality of emission areas LA1, LA2 and LA3 and the non-emission region NLA may be defined by open portions OP (see FIG. 5) and a non-open portion NOP (see FIG. 5) of the pixel-defining film PDL (see FIG. 5), which will be described later. The open portions OP of the pixel-defining film PDL may be located in the emission areas LA1, LA2 and LA3, and the non-open portion NOP of the pixel-defining film PDL may be located in the non-light-emitting area NLA.

In some embodiments, the first emission area LA1, the second emission area LA2 and the third emission area LA3 may form a single group, and a plurality of such groups may be defined in the display area DPA. For example, the first emission areas LA1 may be located in a first sub-pixel SPX1, the second emission areas LA2 may be located in a second sub-pixel SPX2, and the third light emitting areas LA3 may be located in a third sub-pixel SPX3. The first emission areas LA1, the second emission areas LA2 and the third emission areas LA3 may be located in a single pixel PX.

In some embodiments, as shown in FIG. 4, the first emission areas LA1, the second emission areas LA2 and the third emission areas LA3 may include open portions arranged in the first direction DR1. The first emission areas LA1, the second emission areas LA2 and the third emission areas LA3 may be sequentially arranged along the second direction DR2. It is, however, to be understood that the present disclosure is not limited thereto. The arrangement of the first emission areas LA1, the second emission areas LA2 and the third emission areas LA3 may be altered in a variety of ways.

Different lights may exit out of the first emission area LA1, the second emission area LA2 and the third emission area LA3. For example, the first light-emitting area LA1 may emit light of a first color, the second light-emitting area LA2 may emit light of a second color, and the third light-emitting area LA3 may emit light of a third color. The light of the first color may be blue light having a peak wavelength in the range of approximately 440 to 480 micrometers (nm). The light of the second color may be red light having a peak wavelength in the range of approximately 610 to 650 nm. The light of the third color may be green light having a peak wavelength in the range of approximately 510 to 550 nm. It should be understood, however, that the present disclosure is not limited thereto. The light of the second color may be green light and the light of the third color may be red light.

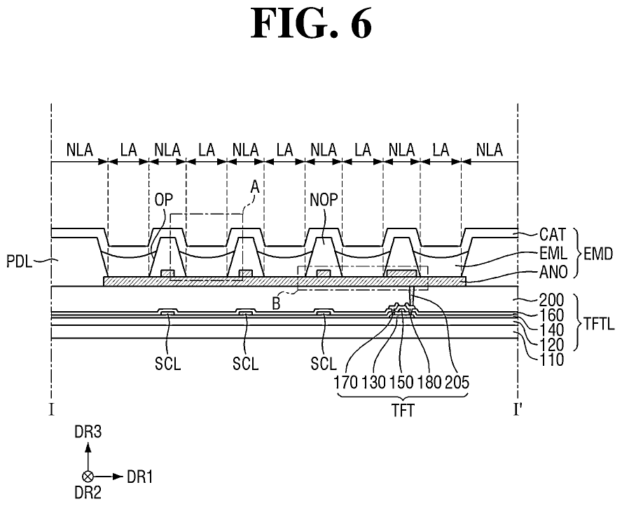

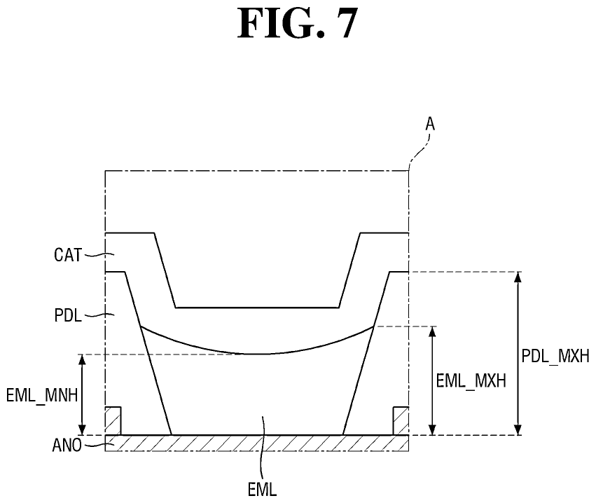

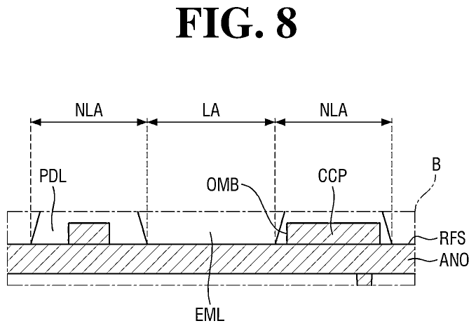

FIG. 5 is a plan view showing a positional relationship between open portions of a pixel-defining film and other elements. FIG. 6 is a cross-sectional view taken along line I-I′ of FIG. 5. FIG. 7 is an enlarged view of part A of FIG. 6. FIG. 8 is an enlarged view of part B of FIG. 6.

Referring to FIGS. 5 and 6, a display device 1 according to an embodiment may include a transistor layer TFTL (e.g., a circuit layer) disposed on a substrate 110, and may include light-emitting elements EMD each including an anode electrode ANO (e.g., a first electrode), an emissive layer EML, and a cathode electrode CAT (e.g., a second electrode). In addition, the display device 1 according to the embodiment may include a pixel-defining film PDL disposed on the transistor layer TFTL to define each of the emission areas LA1, LA2 and LA3 (collectively referred to as “emission area LA”.).

The substrate 110 may be a rigid substrate or a flexible substrate that can be bent, folded, rolled, and so on. The substrate 110 may be made of an insulating material such as glass, quartz and a polymer resin. The examples of the polymer material may be polyethersulphone (“PES”), polyacrylate (“PA”), polyacrylate (“PAR”), polyetherimide (“PEI”), polyethylenenapthalate (“PEN”), polyethyleneterepthalate (“PET”), polyphenylenesulfide (“PPS”), polyallylate, polyimide (“PI”), polycarbonate (“PC”), cellulosetriacetate (“CAT”), cellulose acetate propionate (“CAP”), or combinations thereof. The substrate 110 may include a metal material.

The transistor layer TFTL (e.g., a circuit layer) may be disposed on the substrate 110. The signal lines and the transistors TFT may be disposed in the transistor layer TFTL. The signal lines may include at least one of the data lines DTL, the sensing signal lines SSL, the scan lines SCL, the reference voltage lines RVL, and the first supply voltage line ELVDL described above with reference to FIGS. 2 and 3.

The transistor layer TFTL may include a transistor TFT, a buffer layer 120, a gate insulator 140, an interlayer-dielectric layer 160, and a via-layer 200.

The buffer layer 120 may be disposed on the substrate 110. The buffer layer 120 may be disposed on the substrate 110 to protect the transistor TFT and the light-emitting element EMD from moisture permeating through the substrate 110 that is susceptible to moisture permeation. The buffer layer 120 may be made up of a single layer, or a plurality of inorganic films stacked on one another alternately. For example, the buffer layer 120 may include one of silicon oxide (SiO₂), silicon nitride (SiN) and silicon nitride (SiON), and may be a multilayer in which inorganic films thereof are alternately stacked on one another. It is, however, to be noted that the buffer layer 120 may be eliminated.

A transistor TFT may be disposed on the buffer layer 120. The transistor TFT may include an active layer 130, a gate electrode 150, a source electrode 170, and a drain electrode 180. In FIG. 5, the transistor TFT is implemented as a top-gate transistor in which the gate electrode 150 is located above the active layer 130. It is, however, to be understood that the present disclosure is not limited thereto. That is to say, the transistor TFT may be implemented as a bottom-gate transistor in which the gate electrode is located below the active layer, or as a double-gate transistor in which the gate electrodes are disposed above and below the active layer, respectively.

The active layer 130 may be disposed on the buffer layer 120. The active layer 130 may include polycrystalline silicon, monocrystalline silicon, an oxide semiconductor, etc. When the semiconductor layer includes an oxide semiconductor, the active layer 130 may include a plurality of conductive regions and a channel region therebetween. The oxide semiconductor may be an oxide semiconductor containing indium (In). For example, the oxide semiconductor may be indium-tin oxide (“ITO”), indium-zinc oxide (“IZO”), indium-gallium oxide (“IGO”), indium-zinc-tin oxide (“IZTO”), indium-gallium-tin oxide (“IGTO”), indium-gallium-zinc-tin oxide (“IGZTO”), etc.

In another embodiment, the active layer 130 may include polycrystalline silicon. The polycrystalline silicon may be formed by crystallizing amorphous silicon, and in such case, the conductive regions of the active layer 130 may be doped regions doped with impurities.

A light-blocking layer (not shown) for blocking outside light incident on the active layer 130 may be further disposed between the buffer layer 120 and the active layer 130. When the light-blocking layer is disposed, the light-blocking layer may overlap with the active layer 130 and may be made of an opaque metal material that blocks transmission of light.

The gate insulator 140 may be disposed on the active layer 130. The gate insulator 140 may be disposed on the buffer layer 120, including the active layer 130. The gate insulator 140 may be made up of an inorganic layer including an inorganic film, such as silicon oxide (SiO₂), silicon nitride (SiN) and silicon oxynitride (SiON), or a stack of such materials.

The gate electrode 150 may be disposed on the gate insulator 140. A gate line and one electrode of the capacitor may be further disposed on the same layer as the gate electrode 150. The gate electrode 150 may be disposed to overlap with the active layer 130 in a thickness direction (i.e., third direction DR3). The gate electrode 150 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof. It is, however, to be understood that the present disclosure is not limited thereto.

The interlayer-dielectric layer 160 may be disposed on the gate electrode 150. The interlayer-dielectric layer 160 may work as an insulating film between the gate electrode 150 and other layers disposed thereon. In addition, the interlayer-dielectric layer 160 may be disposed such that it covers the gate electrode 150 to protect it. The interlayer-dielectric layer 160 may be made up of an inorganic layer including an inorganic material, such as silicon oxide (SiO₂), silicon nitride (SiN) and silicon oxynitride (SiON), or a stack of such materials.

The source electrode 170 and the drain electrode 180 may be disposed on the interlayer-dielectric layer 160. Each of the source electrode 170 and the drain electrode 180 may be connected to the active layer 130 through contact holes penetrating through the gate insulator 140 and the interlayer-dielectric layer 160.

The source electrode 170 and the drain electrode 180 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof. It is, however, to be understood that the present disclosure is not limited thereto. Accordingly, the transistor TFT including the active layer 130, the gate electrode 150, the source electrode 170 and the drain electrode 180 may be disposed.

The via-layer 200 may be disposed on the source electrode 170 and the drain electrode 180 to provide a flat surface over the transistor TFT. The via-layer 200 may include a via-hole 205 through which the anode electrode ANO is connected to the transistor TFT. The anode electrode ANO may be connected to the drain electrode 180 of the transistor TFT through the via-hole 205.

The via-layer 200 may include an organic material such as an acryl resin, an epoxy resin, a phenolic resin, a polyamide resin and a polyimide resin, to provide the flat surface. It is, however, to be understood that the present disclosure is not limited thereto.

A pixel-defining film PDL and light-emitting elements EMD may be disposed on the via-layer 200. Each of the light-emitting elements EMD may include the anode electrode AND, the emissive layer EML, and the cathode electrode CAT.

The anode electrode ANO may work as a pixel electrode and may be connected to the drain electrode 180 of the transistor TFT through the via-hole 205.

The anode electrode ANO may be a reflective electrode. The anode electrode ANO may include a reflective layer and a metal oxide layer stacked on the reflective layer. According to an embodiment of the present disclosure, the anode electrode ANO may have a two-layer structure of ITO/Ag, Ag/ITO, ITO/Mg or ITO/MgF₂, or a three-layer structure of ITO/Ag/ITO.

According to the embodiment of the present disclosure, the anode electrode ANO may be a single surface electrode having a monolithic upper surface. Herein, the surface electrode may have a rectangular shape that has longer sides smaller than five times the length of its shorter sides.

According to the embodiment, the anode electrode ANO, which is a single surface electrode, may overlap with all of the plurality of open portions OP and the plurality of emissive layers EML disposed in one sub-pixel SPX.

The shape of the anode electrode ANO will be described in detail later with reference to FIG. 8.

The pixel-defining film PDL may be disposed on the via-layer 200 to cover a part of the anode electrode ANO to define each of the emission areas. The pixel-defining film PDL may partition different pixels. Specifically, emissive layers between adjacent pixels may be at least partially physically separated from each other and spaced apart from each other by the pixel-defining film PDL. The pixel-defining film PDL may define the emission areas LA1, LA2 and LA3 of the pixels PX or the sub-pixels SPX.

The pixel-defining film PDL may include a plurality of open portions OP separated from one another and non-open portion NOP other than the open portions OP. Each of the open portions OP may overlap with the anode electrode ANO and may expose the anode electrode ANO thereunder. The emissive layer EML is located in each of the open portions of the pixel-defining film PDL, and it is ensured by the pixel-defining film that the emissive layers within one pixel are spaced apart and separated from one another. Each of the emissive layers may be surrounded by the pixel-defining film when viewed from the top (i.e., in a plan view).

The pixel-defining film PDL may include an organic material such as an acryl resin, an epoxy resin, a phenolic resin, a polyamide resin, a polyimide resin and an novolak resin, to provide a flat surface.

The shape of the pixel-defining film and its relationship with other elements will be described in detail later with reference to FIG. 5.

The emissive layer EML may be disposed on the anode electrode ANO and the pixel-defining film PDL. The emissive layer EML may diode-connect the anode electrode ANO with the cathode electrode CAT. The emissive layer EML may be disposed in the open portion OP of the pixel-defining film PDL. A plurality of emissive layers EML may be formed in one sub-pixel SPX and may be spaced apart from one another. The emissive layer EML may overlap with the anode electrode ANO and the cathode electrode CAT in the third direction DR3.

In some embodiments, the emissive layer EML may include organic/inorganic light-emitting layers. The organic/inorganic light-emitting layers may include an organic luminescent material, or may include a quantum-dot luminescent material or an inorganic luminescent material such as an inorganic semiconductor.

The organic/inorganic light-emitting layers may emit lights of different colors for different emission areas LA1, LA2 and LA3. For example, the organic/inorganic light-emitting layers of the first emission area LA1 may emit light of a first color, for example, blue light. The organic/inorganic light-emitting layers of the second emission area LA2 may emit light of a second color, for example, red light. The organic/inorganic light-emitting layers of the third emission area LA3 may emit light of a third color, for example, green light.

It is, however, to be understood that the present disclosure is not limited thereto. The emissive layer EML of each of the emission areas LA1, LA2 and LA3 may emit the light of the same color. For example, the emissive layer EML may emit blue light of the first color or white light of a fourth color.

In some embodiments, the emissive layer EML may further include a hole injection layer and/or a hole transport layer interposed between the organic/inorganic light-emitting layers and the anode electrode ANO, in addition to the organic/inorganic emission layers. In addition, the emissive layer EML may further include an electron transport layer and/or an electron injection layer interposed between the organic/inorganic light-emitting layers and the cathode electrode CAT.

The cathode electrode CAT may be disposed on the emissive layer EML. According to the embodiment, the cathode electrode CAT may be conformally formed along the upper surfaces of the pixel-defining film PDL and the emissive layer EML disposed thereunder. The cathode electrode CAT may be in direct contact with the upper surface of the pixel-defining film PDL and the upper surface of the emissive layer EML.

The cathode electrode CAT may have transparency. If the cathode electrode CAT has transparency, it may include Ag, Mg, Cu, Al, Pt, Pd, Au, Ni, Nd, Ir, Cr, Li, Ca, LiF/Ca, LiF/Al, Mo, Ti, or a compound or a mixture thereof, e.g., a mixture of Ag and Mg. In addition, if the thickness of the cathode electrode CAT ranges from several tens to several hundred angstroms, the cathode electrode CAT may be semi-transparent. In addition, the cathode electrode CAT may include a transparent conductive oxide (“TCO”). For example, the cathode electrode CAT may be formed of tungsten oxide (WxOy), titanium oxide (TiO₂), indium tin oxide (ITO), indium zinc oxide (IZO), zinc oxide (ZnO), indium tin zinc oxide (ITZO), magnesium oxide (MgO), etc.

Referring to FIG. 5, in the display device 1 according to the embodiment, the pixel-defining film PDL may include a plurality of open portions OP for each of the sub-pixels SPX. The plurality of open portions OP may expose the anode electrode ANO.

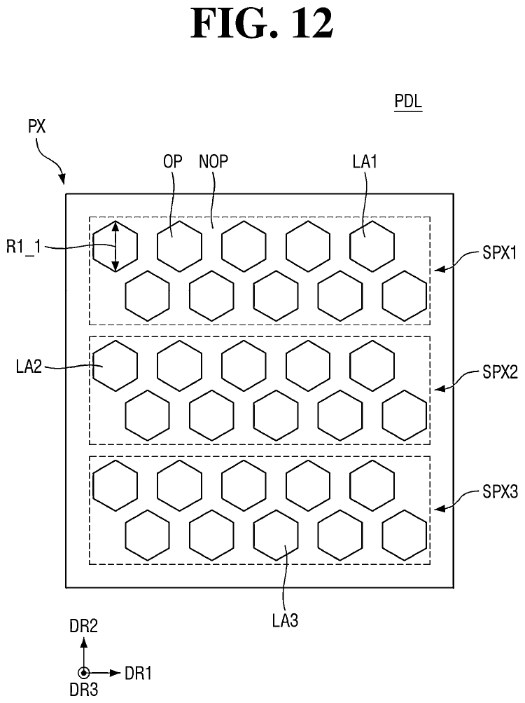

The shape of the open portion OP may have a point symmetry with respect to the center OP_CT of the open portion OP. For example, as shown in the drawings, the open portion OP may have a circular shape when viewed from the top. It should be understood, however, that the present disclosure is not limited thereto. The shape of the open portion OP may be a regular polygon shape as in an embodiment of FIG. 12 to be described later.

When the shape of the open portion OP has a point symmetry, the effect of the coffee ring effect appears equally in all directions, and thus the uniformity of the display device 1 can be effectively improved.

According to the embodiment, the width R1 of the open portion OP may be smaller than the width R2 of the sub-pixel SPX. For example, the width R1 of the open portion OP may range from 25 micrometers (μm) to 30 μm, and the width R2 of the sub-pixels SPX may range from 30 μm to 40 μm.

The plurality of open portions OP may be arranged along the first direction DR1 within the sub-pixels SPX. The centers OP_CT of one of the plurality of open portions OP may be staggered with the center OP_CT of the adjacent one of the open portions OP along the second direction DR2. For example, the centers OP_CT of the odd-numbered open portions OP may be arranged in parallel in the first direction DR1, while the centers OP_CT of the even-numbered open portions OP may be arranged in parallel in the first direction DR1. The centers of the odd-numbered open portions OP may not overlap with the centers of the even-numbered open portions OP in the first and second directions DR1 and DR2.

Referring to FIG. 7, the height of the emissive layer EML may increase from the center to the edge. The upper surface of the emissive layer EML may be concave toward the substrate 110. For example, the emissive layer EML may have the minimum height EML_MNH at its center and the maximum height EML_MXH at its edge.

The height of the upper surface of the emissive layer EML increases from the center to the edge because the coffee ring effect occurs while the ink is dried during the process of forming the emissive layer EML by the inkjet printing. It should be understood, however, that the present disclosure is not limited thereto.

According to the embodiment, the maximum height EML_MXH of the emissive layer EML may be smaller than the maximum height PDL_MXH of the pixel-defining film PDL. The upper surface of the emissive layer EML may be located at a lower level than the upper surface of the pixel-defining film PDL. The cathode electrode CAT conformally formed on the emissive layer EML and the pixel-defining film may be in direct contact with the side surface of the pixel-defining film PDL.

According to this embodiment, the emissive layers EML are disposed in the open portions OP in a sub-pixel SPX, respectively, in the display device 1, so that it is possible to suppress the coffee ring effect. As the coffee ring effect is suppressed, variations in the height of the upper surface of the emissive layer EML can be reduced, and accordingly, the area of the light-emitting portion LEP (see FIG. 9A) can be increased, thereby increasing the luminance of the display device 1. A more detailed description thereon will be given below with reference to FIGS. 9 to 11.

Referring to FIG. 5, the signal lines and the transistors TFT of the transistor layer TFTL may overlap only with the non-open portion NOP. In other words, the signal lines and the transistors TFT of the transistor layer TFTL may be extended around the open portions OP and thus may not overlap with them in the third direction DR3. For example, the transistors TFT may be disposed in the sub-pixel SPX and may not overlap with the open portions OP in the third direction DR3. The data line DRL extended along the second direction DR2 may be spaced apart from the sub-pixel SPX in the first direction DR1 when viewed from the top (i.e., in a plan view).

In some embodiments, the signal lines and the transistors TFT of the transistor layer TFTL may be spaced apart from the open portions OP when viewed from the top.

For example, the signal lines of the transistor layer TFTL may surround at least a part of at least one open portion OP. For example, the scan line SCL extended in the first direction DR1 may overlap with the sub-pixels SPX in the third direction DR3. The scan lines SCL may pass through the sub-pixels SPX in the first direction DR1 when viewed from the top. A scan line SCL may overlap with at least one open portion OP in the first direction DR1 when viewed from the top, and may surround at least a part of the open portion OP. Although the scan line SCL partially surrounds the open portion OP in a straight line shape in the example shown in FIG. 5, the present disclosure is not limited thereto. The scan line SCL may surround it in a curved line shape.

Although the data line DTL, the scan lines SCL and the transistors TFT have been described as an example in this embodiment, this is merely illustrative. At least one of the data line DTL, the sensing signal line, the scan line, the reference voltage line and the first supply voltage line included in the signal lines may be employed as the example.

In some embodiments, the signal lines may be disposed between two adjacent open portions OP. For example, a straight line passing through the centers OP_CT of two adjacent open portions OP may cross the signal lines.

In some embodiments, the signal lines may not completely overlap with all of the open portions OP, but the present disclosure is not limited thereto. For example, the effects according to the embodiment of the present disclosure can be achieved as long as the signal lines overlap with the open portions OP within 10% of the total area of the open portions OP disposed in the sub-pixel SPX. Even in such a case, the uniformity of the film thickness of the emissive layer EML can be improved, and accordingly the effect of improving the luminance of the display device 1 can be equally achieved.

Referring to FIG. 8, the anode electrode ANO may include a reference surface RFS located on its upper surface and protruding portions CCP that are higher than the reference surface RFS. The protruding portions CCP may be formed as the anode electrode ANO overlaps with the signal lines or the transistors TFT in the third direction DR3.

Even though the via-layer 200 is disposed to provide a flat surface over the transistor layer TFTL, there may still be unevenness on the surface of the transistor layer TFTL. As a result, the level differences created by the signal lines or the transistors TFT may be reflected in the anode electrode ANO during the process of forming the anode electrode ANO, and thus the protruding portions CCP may be formed on the upper surface of the anode electrode ANO. In particular, the thinner the via-layer 200 is, the higher protruding portions CCP on the anode electrode ANO are.

At least a portion of the upper surface of the anode electrode ANO overlapping with the open portions OP may be flat. The outermost boundary OMB of the protruding portion CCP of the anode electrode ANO may not overlap the open portions OP in a plan view. For example, the protruding portions CCP may not overlap with the open portions OP but may be located in the non-open portion NOP.

In the display device 1 according to this embodiment, it is possible to prevent level differences from being created in the emissive layer EML as the signal lines do not overlap with the open portions OP, and to reduce deviations in the thickness of the emissive layer EML to thereby improve the uniformity.

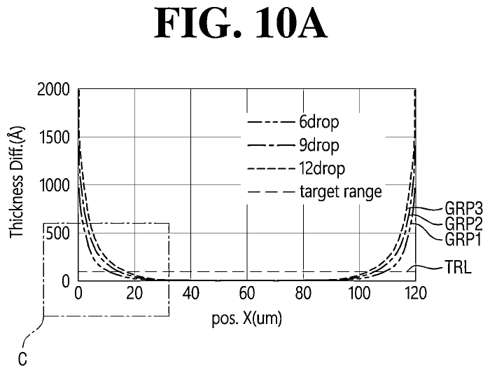

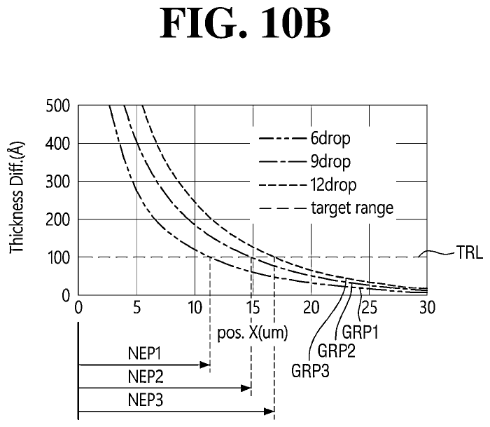

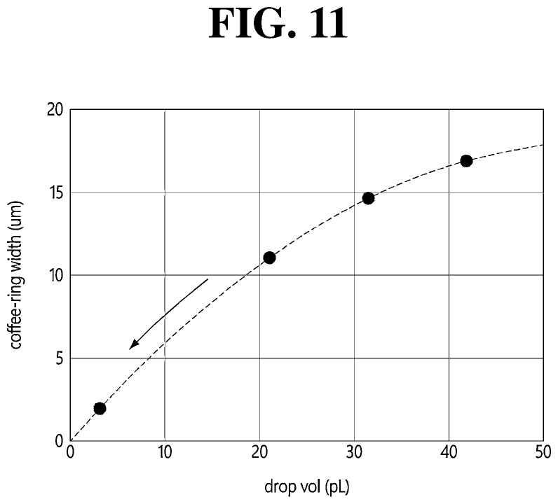

FIGS. 9A and 9B are plan views for comparing light-emitting portions of a sub-pixel according to the embodiment with a light-emitting portion of an existing sub-pixel. FIGS. 10A and 10B are graphs showing variations in the thickness of the emissive layer depending on the amount of an ink ejected into an open portion. FIG. 11 is a graph showing the width of a coffee ring versus the drop volume of an ink ejected onto an open portion.

Referring to FIGS. 9 to 11, FIG. 9A shows a state in which a sub-pixel according to this embodiment emits light, while FIG. 9B shows a state in which an existing sub-pixel emits light.

Depending on its thickness, the emissive layer EML may include a light-emitting portion LEP that emit light and a non-light-emitting portion NLEP that do not emit light. The light-emitting portion LEP and the non-light-emitting portion NLEP may be located in the emission area LA. It should be noted that a physical boundary is shown between the light-emitting portion LEP and the non-light-emitting portion NLEP in the drawings, but the present disclosure it is not limited thereto. For example, the brightness may gradually decrease from the light-emitting portion LEP to the non-light-emitting portion NLEP. In this instance, the region that can satisfy the minimum brightness required by the display device 1 may be defined as the light-emitting portion LEP, while the other region may be defined as the non-light-emitting portion NLEP.

As described above with reference to FIG. 7, the height of the upper surface of the emissive layer EML may increase from the center to the edge due to the coffee ring effect. A part of the emissive layer EML that is higher than the minimum height EML_MNH by a certain factor may not emit light or may have low brightness. Such a part may be the non-light-emitting portion NLEP.

FIG. 10A is a graph showing variations in the thickness of the emissive layer EML depending on the amount of an ink ejected into the open portion OP, and FIG. 10B is an enlarged graph of part C of FIG. 10A.

The graphs shown in FIGS. 10A and 10B are merely illustrative one experimental example, and the numerical values shown in the graph are not limiting. The graphs of FIGS. 10A and 10B will be described as an example for convenience of illustration.

In the graphs of FIGS. 10A and 10B, approximately 3.5 picoliters (pL) of an ink was included per droplet of the ink, and six droplets, nine droplets or twelve droplets were ejected into the open portion OP. In the graphs, a point on the x-axis represents a location in the emissive layer EML in the first direction DR1 or the second direction DR2 in a cross section cut along the third direction DR3, and the y-axis represents deviations between the thickness of the emissive layer EML at that location on the x-axis and the minimum height EML_MNH of the emissive layer EML.

A target range line TRL is defined as a line that represents the maximum thickness deviations allowed for the minimum brightness. The light-emitting portion LEP and the non-light-emitting portion NLEP may be distinguished by the target range line TRL. For example, in this experimental example, a point at which the maximum thickness deviation is 100 Å may be defined as the target range line TRL, an area with the maximum thickness deviation of 100 Å or less may be the light-emitting portion LEP, and an area with the maximum thickness deviation greater than 100 Å may be the non-light-emitting portion NLEP.

Curve GRP1 represents the thickness difference when six droplets are ejected. Curve GRP2 represents the thickness difference when nine droplets are ejected. Curve GRP3 represents the thickness difference when twelve droplets are ejected. The width of the non-light-emitting portion NLEP may be increased from Curve GRP1 to Curve GRP3. For example, the width of the non-light-emitting portion NLEP1 in Curve GRP1 may be the smallest, and the width of the non-light-emitting portion NLEP3 in Curve GRP3 may be the largest. The width of the non-light-emitting portion NLEP2 in Curve GRP2 may be greater than the width of the non-light-emitting portion NLEP1 in Curve GRP1 and smaller than the width of the non-light-emitting portion NLEP3 in Curve GRP3.

FIG. 11 is a graph showing the width of the non-light-emitting portion NLEP, i.e., the width of the coffee ring, depending on the amount of the ink. It can be seen from the graph of FIG. 11 that the width of the coffee ring (y-axis) decreases as the amount of the ink ejected into the open portion OP (x-axis) decreases. This may be because it takes less time to dry a smaller amount of the ink and accordingly the time in which the particles in the ink can move toward the edge is reduced.

The sub-pixel shown in FIG. 9A may include a plurality of open portions OP, whereas the existing sub-pixel shown in FIG. 9B may include one open portion. Although there are five open portions OP according to this embodiment, the number of the open portions is not limited to five.

The horizontal width OP_L1 and the vertical width OP_W1 of the open portions OP according to this embodiment may be smaller than the horizontal width OP′_L1 and the vertical width OP′_W1 of the existing open portion OP′, respectively. For example, the horizontal width OP_L1 and the vertical width OP_W1 of the open portions OP according to this embodiment may each range from approximately 25 μm to 30 μm, while the horizontal width OP′_L1 of the existing open portion OP′ may range from approximately 120 μm to 130 μm, and the vertical width OP′ _W1 of the existing open portion OP′ may range from 30 μm to 40 μm.

The total area of the open portions OP according to this embodiment may be smaller than the total area of the existing open portion OP′. For example, the total area of the open portions OP (e.g., five opening portions) according to this embodiment may range from approximately 2,500 square micrometers (μm²) to 3,500 μm², while the total area of the existing open portion OP′ may range from approximately 4,000 μm² to 5,500 μm². According to some embodiments, the total area of the open portions OP according to this embodiment may range from approximately 60% to 90% of the total area of the existing open portion OP′.

Each of the open portions OP according to this embodiment has a small area, and thus it is possible to form the minimum thickness of the emissive layer EML only with one droplet of the ink per each opening portion OP. On the other hand, the existing open portion OP′ has a large area, and thus at least six droplets of the ink may be required.

The horizontal width NLEP_L1 and the vertical width NLEP_W1 of the non-light-emitting portion NLEP of the open portion OP according to this embodiment in which one droplet of the ink is ejected may each be smaller than each of the horizontal width NLEP′_L1 and the vertical width NLEP′_W1 of the non-light-emitting portion NLEP′ of the existing open portion OP′ in which six droplets of the ink are ejected. For example, the horizontal width NLEP_L1 and the vertical width NLEP_W1 of the non-light-emitting portion NLEP of the open portion OP according to this embodiment may be 1.5 μm and 2.0 μm, respectively, while the horizontal width NLEP′_L1 and the vertical width NLEP′_W1 of the non-light-emitting portion NLEP′ of the existing open portion OP′ may be 10 μm and 12 μm, respectively.

A ratio of the total area of the light-emitting portions LEP to the total area of the open portions OP according to this embodiment may be greater than a ratio of the total area of the light-emitting portion LEP′ to the total area of the existing open portion OP′. For example, the total area of the light-emitting portions LEP of the open portions OP according to this embodiment may be approximately 50% to 60% or more relative to the total area of the existing open portion OP′. The total area of the light-emitting portion LEP′ of the existing open portion OP′ may be approximately 30% to 35% relative to the total area of the existing open portion OP′.

As described above, it is possible to reduce deviations in the film thickness due to the coffee ring effect by reducing the area of each open portion OP in the display device 1 according to this embodiment. Accordingly, it is possible to reduce the width of the non-light-emitting portion NLEP to thereby increase the overall area of the light-emitting portion LEP. By doing so, the luminance of the display device 1 can be increased.

Hereinafter, display devices according to other embodiments of the present disclosure will be described. In the following description, the same or similar elements will be denoted by the same or similar reference numerals, and redundant descriptions will be omitted or briefly described.

FIG. 12 is a plan view showing a pixel of a display device according to another embodiment of the present disclosure.

A display device according to the embodiment of FIG. 12 is different from the display device 1 according to embodiment of FIG. 4 and the like in that the shape of open portions OP of a pixel-defining film PDL is a regular hexagon when viewed from the top (i.e., in a plan view).

More specifically, in the display device 1 according to this embodiment, the shape of the open portions OP of the pixel-defining film PDL may be a regular hexagon when viewed from the top.

As described above, since the emission areas LA1, LA2 and LA3 may be defined by the open portions OP of the pixel-defining film PDL, the shape of the emission areas LA1, LA2 and LA3 may also have a regular hexagonal shape.

When the shape of the open portion OP is a regular hexagon when viewed from the top, which has a point symmetry, changes in the film thickness due to the coffee ring effect occur equally in all directions, and thus the uniformity of the display device 1 can be improved.

The maximum width R1_1 of the open portion OP of the display device 1 according to this embodiment may be equal to the width R1 of the open portion OP of the display device 1 according to the above embodiment.

According to this embodiment, the shape of the open portions OP in the display device 1 is a regular hexagon when viewed from the top, which allows for more efficient utilization of space than the open portions having a circle shape. For example, when the shape of the open portions OP is a regular hexagon when viewed from the top, a greater number of open portions may be formed than the open portions with the same width in a circular shape in the sub-pixel SPX having the same area, and a larger open portion per sub-pixel SPX can be achieved. By doing so, the brightness of the display device 1 can be improved.

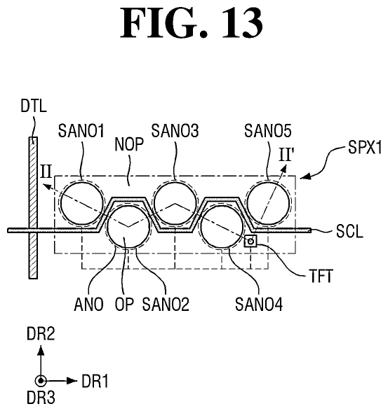

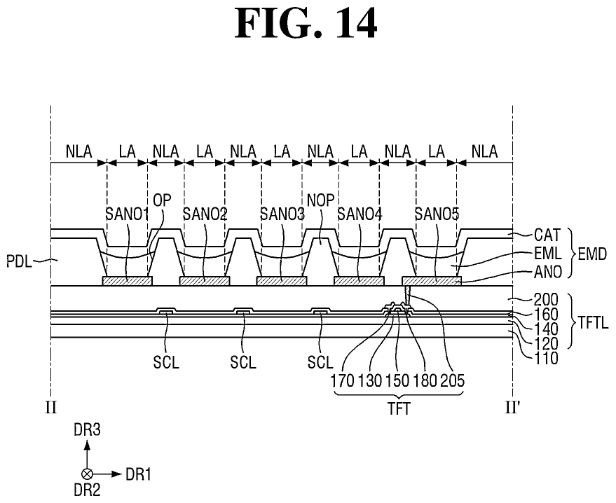

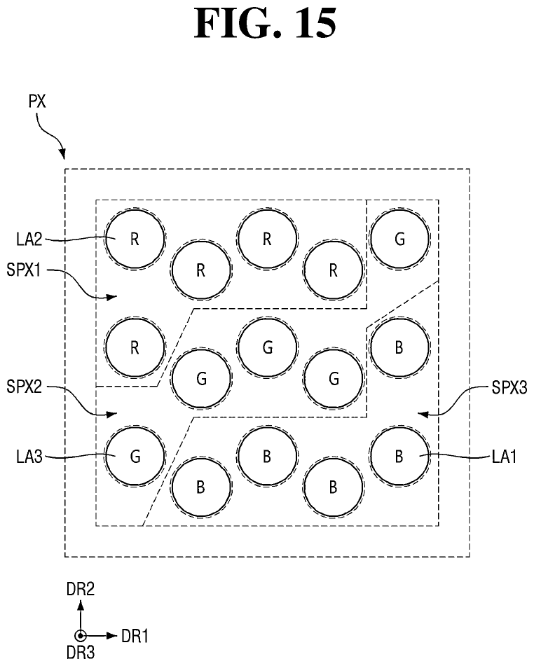

FIG. 13 is a plan view showing a sub-pixel of a display device according to yet another embodiment of the present disclosure. FIG. 14 is a cross-sectional view taken along line II-II′ in FIG. 13. FIG. 15 is a plan view showing a pixel of a display device according to the embodiment of the present disclosure.

A display device according to the embodiment of FIGS. 13 to 15 is different from the display device 1 according to the embodiment of FIG. 6 and the like in that an anode electrode ANO includes a plurality of sub-electrodes instead of a single surface electrode.

More specifically, the anode electrode ANO may include a plurality of sub-electrodes SANO1, SANO2, SANO3, SANO4 and SANO5.

The plurality of sub-electrodes SANO1, SANO2, SANO3, SANO4 and SANO5 may overlap with at least one of the plurality of emissive layers EML disposed in one sub-pixel SPX. For example, as shown in the drawings, the sub-electrodes SANO1, SANO2, SANO3, SANO4 and SANO5 may overlap with the emissive layers EML, respectively. It should be understood, however, that the present disclosure is not limited thereto. The first sub-electrode SANO1 and the second sub-electrode SANO2 may be formed as one and overlap with two emissive layers EML. In other words, each of the plurality of sub-electrodes SANO1, SANO2, SANO3, SANO4 and SANO5 may overlap with a plurality of emissive layers EML.

The sub-electrodes SANO1, SANO2, SANO3, SANO4 and SANO5 may be electrically connected with one another via separate signal lines. According to the embodiment of the present disclosure, the fifth sub-electrode SANO5 may be connected to a transistor TFT through a via-hole 205. The first sub-electrode SANO1 to fourth sub-electrode SANO4 may be electrically connected to the fifth sub-electrode SANO5 and connected to the transistor TFT.

Referring to FIG. 15, when the anode electrode ANO is implemented as the plurality of sub-electrodes SANO1, SANO2, SANO3, SANO4 and SANO5 as in the display device 1 according to this embodiment, the arrangement of the sub-pixel SPX can be altered in a variety of ways in the pixel PX. For example, when the anode electrode ANO is an integral planar electrode, the sub-pixel SPX should be formed in a shape similar to that of the anode electrode ANO. In contrast, when the anode electrode ANO includes a plurality of sub-electrodes SANO1, SANO2, SANO3, SANO4 and SANO5, the sub-pixel SPX may not be affected by the shape of the anode electrode ANO.

For example, a first sub-pixel SPX1 and a third sub-pixel SPX3 may have an L-shape extended in the first and second directions DR1 and DR2, and a second sub-pixel SPX2 may be extended along a diagonal direction different from the first and second directions DR1 and DR2. It is to be understood that the shape of the sub-pixel SPX is not limited thereto, and the first sub-pixel SPX1 to the third sub-pixel SPX3 may be arranged sequentially and repeatedly in one pixel PX.

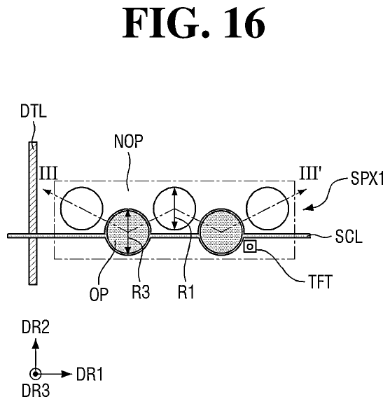

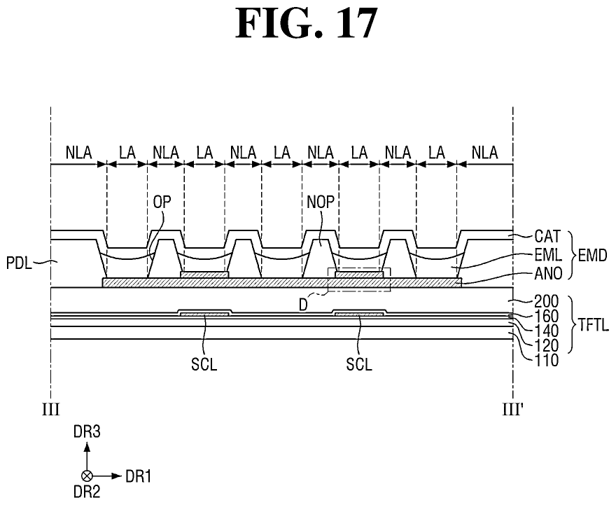

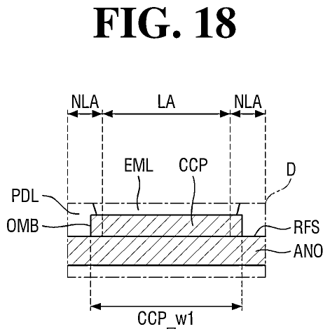

FIG. 16 is a plan view showing a sub-pixel of a display device according to yet another embodiment of the present disclosure. FIG. 17 is a cross-sectional view taken along line III-III′ of FIG. 16. FIG. 18 is an enlarged view of part D of FIG. 17.

A display device according to the embodiment of FIGS. 16 to 18 is different from the display device 1 according to embodiment of FIG. 5 and the like in that signal lines overlap with at least one open portion OP entirely.

More specifically, in the display device 1 according to this embodiment, the signal lines of the transistor layer TFTL may overlap with at least one open portion OP entirely.

For example, referring to FIG. 16, a scan line SCL extended in the first direction DR1 may overlap with at least one open portion OP in the third direction DR3. The scan line SCL may overlap with the at least one open portion OP entirely. The width R3 of the scan line SCL may be greater than or equal to the width R1 of the at least one open portion OP with it overlaps with the at least one open portion OP.

The display device according to the embodiment of FIGS. 17 and 18 is identical to the display device 1 according to the above embodiment in that The upper surface of the anode electrode ANO may be flat where it overlaps with the open portions OP, and that the outermost boundary OMB between the reference surface RFS and the protruding portions CCP of the anode electrode ANO may not overlap with the open portions OP. For example, according to this embodiment, the protruding portion CCP is located such that it overlaps the open portion OP, and thus the upper surface of the protruding portion CCP may be flat.

Incidentally, in the display device 1 according to this embodiment, the protruding portion CCP may overlap with both the open portion OP and the non-open portion NOP. According to the embodiment, the width CCP_wl of the protruding portion CCP may be greater than or equal to the width R1 of the open portion OP.

In the display device 1 according to this embodiment, instead of disposing the signal lines such that they do not overlap with the open portions OP, the signal lines overlap with the open portion OP with the expanded width so that the outermost boundary OMB between the reference surface RFS and the protruding portion CCP is not located inside the open portion OP. In this manner, it is possible to prevent level differences from being created in the emissive layer EML, and it is possible to improve the uniformity by reducing deviations in the thickness of the emissive layer EML.

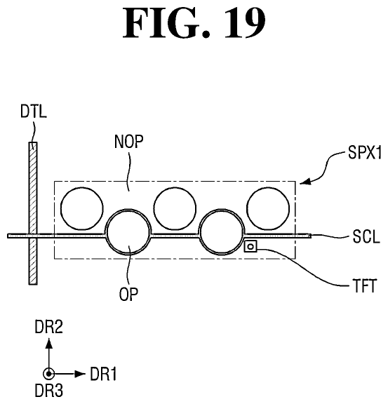

FIG. 19 is a plan view showing a sub-pixel of a display device according to yet another embodiment of the present disclosure.

A display device according to the embodiment of FIG. 19 is different from the display device 1 according to embodiment of FIG. 5 and the like in that signal lines surround an entirety of at least one open portion OP.

More specifically, the display device 1 according to this embodiment is identical to the display device 1 according to the above embodiment in that signal lines and transistors TFT of the transistor layer TFTL may overlap only with the non-open portion, that the signal lines and the transistors TFT of the transistor layer TFTL may be extended around the open portions OP so that they do not overlap with the open portions in the third direction DR3, and that the signal lines and the transistors TFT of the transistor layer TFTL may be spaced apart from the open portions OP when viewed from the top (i.e., in a plan view).

Incidentally, in the display device 1 according to this embodiment, the signal lines of the transistor layer TFTL may surround an entirety of at least one open portion OP. For example, a scan line SCL extended in the first direction DR1 may overlap with at least one open portion OP in the first direction DR1 when viewed from the top, and may surround an entirety of the at least one open portion OP. Although the scan line SCL surrounds an entirety of the open portion OP in a curved shape in the example shown in FIG. 19, the present disclosure is not limited thereto. The scan line SCL may surround it in a straight line shape.

Although the scan line SCL has been described as an example in this embodiment, this is merely illustrative. At least one of the data line DTL, the sensing signal line, the scan line, the reference voltage line and the first supply voltage line included in the signal lines may be employed as the example.

In the display device 1 according to this embodiment, it is possible to prevent level differences from being formed in the emissive layer EML as the signal lines do not overlap with the open portions OP, and to reduce deviations in the thickness of the emissive layer EML to improve the uniformity.

According to some embodiments, a scan line SCL may branch into a plurality of scan lines SCL where the scan line SCL surrounds an entirety of the open portions OP, and the branched scan lines SCL may be connected in parallel.

In the display device 1 according to this embodiment, since the signal lines are arranged to completely surround the open portions OP, the branched signal lines connected in parallel can increase the overall area of the signal lines to thereby reduce the electrical resistance.

In concluding the detailed description, those skilled in the art will appreciate that many variations and modifications can be made to the preferred embodiments without substantially departing from the principles of the invention. Therefore, the disclosed preferred embodiments of the invention are used in a generic and descriptive sense only and not for purposes of limitation.

What is claimed is:

1. A display device comprising:
a substrate;
a first electrode disposed on the substrate;
a pixel-defining film comprising a plurality of open portions exposing the first electrode;
a plurality of emissive layers overlapping with a monolithic surface of the first electrode in a plan view and disposed in the plurality of open portions, respectively; and
a second electrode disposed on the plurality of emissive layers.

2. The display device of claim 1,
wherein at least a portion of an upper surface of the first electrode overlapping with the open portions is flat.

3. The display device of claim 2,
wherein the first electrode comprises a reference surface located on the upper surface of the first electrode and protruding portions that are higher than the reference surface, and
wherein outermost boundaries of the protruding portions do not overlap with the exposed portion of the first electrode in the plan view.

4. The display device of claim 3,
wherein the protruding portion does not overlap with the exposed portion of the first electrode in the plan view.

5. The display device of claim 3,
wherein the protruding portions overlap with the exposed portion of the first electrode as well as other portions of the first electrode except for the exposed portion in the plan view.

6. The display device of claim 1, further comprising:
a circuit layer disposed between the substrate and the first electrode,
wherein the circuit layer comprises signal lines and thin-film transistors, and
wherein the signal lines and the thin-film transistors do not overlap with the open portions in the plan view.

7. The display device of claim 6,
wherein the signal lines comprise at least one of a data line, a sensing signal line, a scan line, a reference voltage line, and a supply voltage line.

8. The display device of claim 6,
wherein the signal lines are arranged to be spaced apart from the open portions in the plan view, and
wherein the signal lines overlap with at least one of the plurality of open portions in a cross-sectional view, and surround at least a part of the at least one open portion in the plan view.

9. The display device of claim 8,
wherein the signal lines surround an entirety of the at least one open portion in the plan view.

10. The display device of claim 1, further comprising:
a circuit layer disposed between the substrate and the first electrode,
wherein the circuit layer comprises signal lines and thin-film transistors,
wherein an entirety of at least one of the open portions overlaps with the signal lines in the plan view.

11. The display device of claim 10,
wherein a width of the signal lines is greater than or equal to a width of the at least one open portion in an area where the signal lines overlap with the at least one open portion.

12. The display device of claim 1,
wherein the first electrode is a single surface electrode.

13. The display device of claim 1,
wherein the first electrode comprises a plurality of patterned sub-electrodes,
wherein the sub-electrodes are electrically connected with one another, and
wherein each of the sub-electrodes overlaps with at least one of the plurality of emissive layers in the plan view.

14. The display device of claim 1,
wherein the second electrode is in direct contact with the pixel-defining film at side surfaces of the open portions.

15. The display device of claim 14,
wherein the second electrode is in direct contact with an upper surface of the pixel-defining film disposed on an area other than the open portions.

16. The display device of claim 1,
wherein a shape of each of the open portions has a point symmetry with respect to its center in the plan view.

17. The display device of claim 1,
Wherein, in an emissive layer of the plurality of emissive layers, a height of an upper surface of the emissive layer increases from a center to an edge of the emissive layer, and
wherein the upper surface of the emissive layer has a shape concave toward the substrate.

18. The display device of claim 17,
wherein the emissive layer comprises a light-emitting portion and a non-light-emitting portion surrounding the light-emitting portion, and
wherein deviation between a minimum height and a maximum height of the emissive layer in the light-emitting portion is equal to or less than 100 angstroms (Å).

19. A display device comprising:
a substrate;
a first electrode disposed on the substrate;
a plurality of emissive layers spaced apart from one another on a monolithic surface of the first electrode and comprising an organic material; and
a second electrode disposed on the plurality of emissive layers,
wherein each of the plurality of emission layers overlaps with the first electrode and the second electrode.

20. The display device of claim 19,
wherein the plurality of emissive layers is configured to diode-connect the first electrode with the second electrode.
